(19) United States
(12) Patent Application Publication
(10) Pub. No.: US 2011/0148050 A1
(43) Pub. Date: Jun. 23, 2011

(54) SEALING ARTICLE

(76) Inventors: Klaus-Dieter Vissing, Morsum (DE); Gabriele Neese, Bremen (DE); Alfred Baalmann, Osterholz-Scharmbeck (DE); Peter Stauga, Blender (DE)

(21) Appl. No.: 12/997,974

(22) PCT Filed: Jun. 18, 2009
(86) PCT No.: PCT/EP2009/057596

§ 371 Date: Mar. 7, 2011

(30) Foreign Application Priority Data
Jun. 18, 2008 (DE) 10 2008 002 515.1

(51) Int. Cl. F16J 15/02; C23C 16/50; C23C 16/56

(52) U.S. Cl. 277/650; 427/578

(57) ABSTRACT

The present invention relates to a sealing article comprising an elastomeric and/or polymeric substrate and a plasma polymeric coating arranged thereon and consisting of carbon, silicon, oxygen, hydrogen and (i) fluorine or (ii) no fluorine and optionally usual impurities, the following relationships applying to the substance amount ratios in the plasma polymeric coating:

1.3:1≦n(O):n(Si)≦3.0:1

0.3:1≦n(C):n(Si)≦5.0:1 and preferably

0.5:1≦(n(H)+n(F)):n(C)≦3.0:1.

The invention relates to a sealing article, comprising an elastomeric and/or polymeric substrate and a plasma polymeric coating which is arranged thereon and consists of carbon, silicon, oxygen and hydrogen and optionally usual impurities in specific substance amount ratios and preferably in a specific degree of cross-linking. The invention also relates to the use of a specific plasma polymeric coating to improve the dynamic loadability of an elastomeric and/or polymeric substrate and to a process for the production of a corresponding sealing article.

An optimization between abrasion resistance, friction reduction, thermal conductivity, temperature stability, chemical stability and elasticity of the sealing body is desirable particularly for dynamically loaded sealing articles (sealing bodies), the function of which it is, when sealing moving machine parts of two chambers which have a common moving interface, to prevent or minimize the exchange of liquids and/or gases. Typically, a corresponding seal can be achieved with the aid of piston rings, O rings, sealing edge rings, radial rotary shaft seals, floating ring gap seals, sliding ring seals or labyrinth seals. Elastomeric and/or polymeric materials are suitable for the actual sealing bodies. Although when used on their own they have the necessary elasticity, they do not often have the desired wear resistance and/or the desired friction coefficient and/or the desired surface energy for the use of corresponding lubricating agents. Accordingly, approaches were known in the past by which the wear and/or sealing characteristics of elastomeric and/or polymeric sealing articles were to be improved by an additional coating.

Chemically repelling, low-energy plasma polymeric coatings, in particular those of organosilicon precursors have been known for many years. They have easy-to-clean characteristics (WO 03/002269 A1), they can act as an interlayer (DE 100 34 737 A1) and, in spite of their three-dimensional cross-linking nature, they can even have elastomeric characteristics (WO 2007/118905) A1. Basic interlayer coatings were used as an anti-tack coating for rubber materials to reduce the “tackiness” thereof, for example to allow the simple, reproducible release of a valve from a valve seat or to allow the easy assembly of O rings. Avoiding the surface tackiness also reduces the sliding friction characteristics as solids-solids friction. This is noticeable in a positive manner particularly where there are very low contact pressures. Many of these layers cannot meet the requirements of increased mechanical wear. In the case of increased contact pressures on the friction partner, as used for sliding ring seals, these layer systems rapidly fail, in particular an adhesion wear occurs.

Other application areas of this type of thin layer which impose increased demands on the mechanical stability, for example non-stick coatings for pans, bread baking tins or parts for machines are unsuitable therefor. Their mechanical stability of use is inadequate. Mechanically resistant coatings of this group of materials are instead similar to SiO₂ and require layer thicknesses of 2 to 8 μm, depending on use and substrate.

Furthermore, it is also known that the sliding characteristics of the low-energy, organosilicon layers are poor in many cases, in spite of the improvement described above, so that a coating with an integrated lubricant depot is described in DE 10 2005 052 408 A1. However, due to the low quantitative content, this is not suitable for permanent use in a dynamically loaded seal.

It is also known from DE 10 2004 010 498 A1 to provide fixed sealing rings of a pump piston with a coating which consists predominantly of DLC (diamond like carbon) to increase the wear resistance and to improve the friction coefficients. There is no detailed information about the material configuration of the coating on the elastomer or about the characteristics of the coating. However, in the embodiments there is a reference to a high thermal load during coating, as well as references to process gases, such as acetylene, methane or mixtures thereof. From this, a person skilled in the art will conclude that conventional, friction-reducing wear protection layers are also deposited in this case on the sealing ring.

In other publications, for example DE 103 52 674 A1, the elastomer is coated with a curable substance at least in the sealing region, which curable substance contains friction-reducing elements. In this respect, PTFE in particular is mentioned. Other solutions prefer a lubricating varnish.

DE 198 39 502 A1 points in a similar direction; here, for an elastomeric sealing body with a double sealing lip, the stronger contacting sealing lip is covered with a PTFE film.

Approaches are known from DE 10 2005 025 253 A1 and DE 10 2005 041 330 A1 to use seals of elastomeric moldings, the surfaces of which are modified by plasma polymer technology and on which corresponding layers are deposited. DE 10 2005 041 330 A1 considers the surface modification by means of plasma grafting and some of the layers disclosed in DE 10 2005 025 253 A1 are not adequately specified. However, if this is the case, they do not exhibit optimum characteristics for the desired use particularly in their wear behavior and/or their surface energy.

Against the background of the already known prior art, the object of the invention was to provide a sealing article which has an improved overall characteristic profile compared to the prior art for dynamic loads. Characteristics which were to be improved in this context were in particular the achievement of a greater wear resistance, the prolonging of the service life, an increase in the temperature resistance, an increase in the wettability in particular for lubricating agents and/or an improvement in the leakage and/or friction behavior. In this respect, the mentioned improvements should preferably be noticed in areas of use with a deficient lubrication in the sealing region and/or for typical contact pressures within a range of from 0.05 to 5 N/mm².

This object is achieved by a sealing article comprising an elastomeric and/or polymeric substrate and a plasma polymeric coating which is arranged thereon and consists of carbon, silicon, oxygen, hydrogen and (i) fluorine or (ii) no fluorine and optionally usual impurities, the following relationships applying to the substance amount ratios in the plasma polymeric coating:

1.3:1≦n(O):n(Si)≦3.0:1

0.3:1≦n(C):n(Si)≦5.0:1 and preferably

0.5:1≦(n(H)+n(F)):n(C)≦3.0:1, preferably ≦2.5 (particularly when the coating does not contain any fluorine).

Some of the layers provided according to the invention on the elastomeric substrate are known from WO 03/002269. However, there is no indication at all of the use of the layers in connection with elastomers, in particular of the surprisingly high wear resistance in connection with elastomeric and/or polymeric sealing articles (sealing bodies), furthermore in particular those which are exposed to dynamic loads.

In the present context, a “plasma polymeric layer” or coating is a layer which can be produced by plasma polymerization. Plasma polymerization is a process in which gaseous precursors (often also called monomers) are stimulated by a plasma and are deposited on a freely selectable substrate as a highly cross-linked layer. A prerequisite for a plasma polymerization is the presence of chain-forming atoms, such as carbon or silicon in the working gas. Due to the stimulation, the molecules of the gaseous substance (precursors) are fragmented by the bombardment with electrons and/or high-energy ions. This produces highly stimulated radical or ionic molecular fragments which react together in the gas chamber and are deposited on the surface to be coated. The electrical discharge of the plasma and the intensive ion and electron bombardment thereof continuously acts on this deposited layer so that further reactions can be initiated in the deposited layer and an intensive linking of the deposited molecules can be achieved.

In the present context, the term “plasma polymeric layer” also includes layers which can be produced by plasma-enhanced CVD (PE-CVD). In this case, the substrate is also heated to control the process. Thus, SiO₂ coatings can be produced from silane and oxygen. Furthermore, it is explicitly mentioned that atmospheric pressure plasma processes can also be used to produce plasma polymeric layers to be used according to the invention, although at present low pressure plasma polymerization processes are preferred.

In the present context, substances which are supplied to a plasma as gas or vapor for the layer formation via a plasma polymerization are called “monomers” (gaseous precursors). Those liquids are called “liquid precursors” which can be cross-linked for example by the effect of a plasma (for example by highly exited particles, electrons or UV radiation), without previously evaporating.

In this respect, the substance amount ratios for the coating to be used according to the invention are preferably determined by ESCA (electron spectroscopy for chemical analysis) often also called XPS investigation (XPS=x-ray photoelectron spectroscopy). More preferably, the ECSA measurement relates to the side of the coating remote from the substrate.

To determine the hydrogen contents, a micro-elementary analysis for hydrogen and carbon is preferably used instead of ESCA, so that the ratio of carbon to hydrogen is thus determined. When evaluating the data, a person skilled in the art should further consider that no Si—H signal or only a very low Si—H signal can be measured by FTIR, so that hydrogen is to be assigned exclusively to carbon as a bonding partner.

The displacement of the Si 2p peak or of the O 1s peak which can be observed during the ESCA measurement gives an indication of the degree of cross-linking inside the plasma polymeric coating. A trimethylsiloxy-terminated polydimethylsiloxane (PDMS) with a kinematic viscosity of 350 mm²/s at 25° C. and with a density of 0.970 g/mL at 25° C. is the product DMS-T23E produced by Gelest.

To determine the peak displacement, the measuring device is calibrated, as mentioned, such that the aliphatic proportion of the C 1s peak is at 285.00 eV. Due to charging effects, it will usually be necessary to displace the energy axis without further modification to this fixed value. Reference is also made explicitly to WO 2007/118905 for carrying out the ESCA measurements particularly in respect of the peak displacement.

Usual impurities in the context of the present invention are elements apart from the aforementioned elements O, Si, C, H and F which are incorporated into the coating by the coating process (usually plasma process), and originate from the elastomeric and/or polymeric substrate. In this respect, the content of these usual impurities is preferably ≦10 atom %, more preferably ≦5 atom %, particularly preferably ≦2 atom % and most particularly preferably ≦1 atom %, based on the total of all atoms contained in the plasma polymeric coating. It is stressed once again that the usual impurities explicitly do not include the contents of carbon, silicon, oxygen, hydrogen and fluorine which also originate from the substrate to be coated. Examples of usual impurities are sodium and zinc.

Preferred according to the invention is a sealing article which is suitable for dynamic loads. The function of dynamically loaded sealing articles has been defined above. A person skilled in the art will make a suitable choice of substrate such that a sealing article is suitable for a dynamic load. Preferred substrates are stated further below. Furthermore, a person skilled in the art would naturally also select the spatial configuration of the sealing article such that it is adapted to its function. Typical embodiments of such sealing articles have also been stated above.

It has surprisingly been found that the coatings prove to be markedly stable in sealing articles according to the invention. This even applies under the conditions of dynamic loads. In this respect, it will be preferable in many cases to produce the coating without fluorine, since an increased expense in terms of apparatus is required for the use of fluorine because of its aggressiveness. However, in many other cases it will often be preferred to use fluorine in order to make use of the particular characteristics thereof.

Surprisingly, in many cases the ratio of oxygen to silicon is significant for the characteristics of the plasma polymeric coating in the sealing article according to the invention. In an adequate characteristic profile, the ratio of carbon to silicon can vary over a relatively wide range. In this respect, it should be considered that during the coating process on a carbon-containing substrate, significant portions of carbon are usually incorporated into the coating from the substrate. However, it has been found that the characteristic profile of the coatings improves in particular during use for sealing articles with dynamic loads when the ratio of carbon to silicon decreases, starting from 5.

The coating on the article according to the invention preferably optionally also comprises a substance amount ratio of O:Si≧1.4 and preferably ≦2.6 and more preferably <2.3.

The ratio of C:Si is preferably ≧0.5, again preferably ≧0.6 and optionally also preferably ≦3.0, and in each case more preferably ≦1.8, ≦1.7, ≦1.6.

The ratio of (H+F):C is preferably ≧0.7 and at the same time <2.5, more preferably <2.3 and more preferably <2.0.

The substance amount ratios mentioned in the present context are in each case the ratios of the atomicities of the individual elements relative to one another, unless indicated otherwise.

In preferred coatings, the Si 2p peak under the aforementioned conditions is displaced by more than 0.4, preferably more than 0.45, more preferably more than 0.5 eV to higher bonding energies and/or the O 1s peak is displaced by more than 0.5 eV to higher bonding energies, in each case in the ESCA spectrum on the side of the plasma polymeric layer remote from the substrate, with calibration on the aliphatic proportion of the C 1s peak at 285.00 eV, compared to a trimethylsiloxy-terminated polydimethylsiloxane (PDMS) with a kinematic viscosity of 350 mm²/s at 25° C. and a density of 0.97 g/mL at 25° C.

A person skilled in the art primarily adjusts the substance composition and thus the characteristics of the plasma polymeric coating using the following measures, for example: type of precursor, mixture ratio of the precursors, process gases, process duration, gas mixture or the gas mixture ratio. However, in so doing, he also considers the composition of the substrate, because fractions of said substrate can be incorporated into the plasma polymeric coating.

With a predetermined material type of the gas to be processed (precursor), a person skilled in the art will adjust the hardness and the cross-linking and, resulting therefrom, the corresponding peak displacements primarily by the ratio of the precursors to one another, the total quantity of gas and the power used to maintain the plasma. Reference is made to ISBN 978-3-86727-548-4 “Aufskalierung plasmapolymerer Beschichtungsverfahren” [Up-scaling of plasma polymeric coating processes], chapters 2 and 7 by Dr. Klaus Vissing concerning the effects of these measures and for further information about the control of the process.

An article according to the invention is preferred in which the surface energy of the plasma polymeric coating on the side remote from the substrate is from 25-40 mN/m, determined in a dynamic contact angle measurement with the liquids water, ethylene glycol, diiodine methane, glycol, n-decane, benzyl alcohol and evaluated by Wu's method and/or the hardness (measured by nanoindentation) of the plasma polymeric coating is from 1-5 GPa, preferably from 1.5-4 GPa. Lit. (nanoindentation): W. C. Oliver, G. M. Pharr, J. Mater. Res. 7 1564 (1992); A. C. Fischer-Cripps: Nanoindentation, Springer, N.Y. (2002), G. M. Pharr, Mat. Sci. Eng. A 253 151 (1998), K. L. Johnson, Contact Mechanics, Cambridge University Press, Cambridge, (1985). Lit. (Contact angle measurement): John C. Berg, ed., Wettability, Marcel Dekker, 1993, 0824790464; Milan Johann Schwuger, Lehrbuch der Grenzflächenchemie [Textbook of interfacial chemistry], Georg Thieme Verlag, 1996, 3131375019.

The surface energy of the coating of the article according to the invention is preferably 25 to 35 Nm/m and/or the hardness is from 1.5 to 4 GPa.

The coating is particularly preferably adjusted such that it has a low modulus of elasticity with a high hardness, so that it has a high elastic deformability at the same time as a high hardness. Those coatings whose quotient of hardness and modulus of elasticity is ≧0.1, preferably ≧0.11 have proved to be particularly suitable. This can be achieved particularly effectively using plasma coating devices which operate at frequencies in the MHz range and couple in capacitively. In this respect, the substrate is arranged such that it preferably floats freely in the reactor.

Due to the structure, similar to a duromer, of the plasma polymeric layer, and to the hardness and low friction coefficient thereof, the adhesion wear on an elastomeric and/or polymeric body is significantly reduced. Consequently, the wear coefficient, defined as the quotient of the removed volume Vᵣₑₘ divided by the normal force F_{N} and the running length L, can be greatly reduced. The wear coefficient is ≦3*10⁻³ mm³/N km, preferably ≦3*10⁻⁴ mm³/N km, more preferably 3*10⁻⁵ mm³/N km.

A person skilled in the art can influence the surface energy and/or the hardness for example by the following measures: changing the content of oxygen-containing gases, the selected total quantity of gas, the power and a re-activation of the surface, in which case the layer-forming precursors are not supplied to the plasma for a short period of time, just non-oxygen-containing gases. It is often preferred to increase the number of polar groups in the coating respectively in the surface, so that for example the ratio of HMDSO to O₂ is changed in favor of O₂ or the total gas flow is reduced while the coupled power remains the same (more power per gas particles) or the power is increased while the quantity of gas and the gas composition remains the same. Combinations of these measures are also possible.

The measures described in the previous paragraph ultimately do not result in just an increased incorporation of oxygen in the coating and thus in a higher surface energy, but they also result in a decrease in the hydrocarbon content. The cross-linking conditions change, the coatings become harder and more brittle. A person skilled in the art can test this, for example using FTIR spectroscopy, ESCA analysis and nanoindentation for measuring hardness and can make deliberate adjustments by controlling the process.

Within the specified parameter fields (for example, surface energy and hardness), the article according to the invention is particularly suitable for use in systems in which the primary sealing gap to be sealed is a dynamic sealing gap.

An article preferred according to the invention is one in which the coating withstands, undamaged, thermal loads of up to 300° C., and preferably also withstands, undamaged, a temperature of 380° C. for up to 5 minutes. In the present context, “undamaged” means in particular that the surface energy and the composition remain unchanged in the FTIR spectrum, respectively in XPS analysis.

The coating preferably has a thermal conductivity of from 0.1 to 1.3 W/mK. This is basically determined by the material composition of the coating. The thermal conductivity increases with an increasing cross-linking, in other words with an increasing surface energy and hardness.

A person skilled in the art can influence the thermal resistance, for example by the material composition and the degree of cross-linking. The measures to be taken are comparable with those for increasing the hardness. In this respect, reference is also made, for example to ISBN 3-8265-9216-6 “Charakterisierung der spektroskopischen Eigenschaften von Metall- and Halbleiterclustern in plasmapolymeren Matrizen” [Characterization of the spectroscopic characteristics of metal and semi-conductor clusters in plasma polymeric matrices] by Dr. Dirk Salz, chapter 4.

The sealing article according to the invention preferably has a sliding friction coefficient (also dynamic friction coefficient) of ≦0.25, preferably ≦0.2 in respect of stainless steel (1.4301). The dynamic friction coefficient decreases when the oxygen content in the plasma and/or the power is increased. Such a low dynamic friction coefficient significantly reduces the wear of the coating. The inlet wear is likewise reduced. The sliding friction coefficient is preferably determined according to Example 1.

When determining the friction characteristics, such as sliding friction coefficient or static friction coefficient, it must be borne in mind that particularly in the case of sealing articles according to the invention in which the coating provided according to the invention is relatively thin, a total system is always considered whose friction characteristics are not only influenced by the outermost coating, but additionally by the substrate. Thus, a person skilled in the art is presented with further adjustment possibilities by suitable combinations of substrate and coating in order to achieve the sliding friction coefficient facilitated according to the invention for the sealing articles according to the invention. In particular, it can be advantageous if the article according to the invention comprises as substrate a polymer which is not an elastomer, that the sealing article has a sliding friction coefficient of ≦0.25 on the side of the polymeric coating remote from the substrate.

Dry friction is suppressed as far as possible by the combination of the low dynamic friction coefficient and a surface energy which allows a wetting with lubricating substances, for example oils or greases.

An article according to the invention preferably comprises a plasma polymeric coating which, based on 100 atom % for the total of the elements silicon, oxygen and carbon, contains:

| | |
|---|---|
| silicon | 12 to 30 atom %, preferably 22 to 30 atom % |
| oxygen | 16 to 60 atom %, preferably 28 to 60 atom % |
| carbon | 10 to 69 atom %, preferably 10 to 50 atom %. |

A preferred article according to the invention comprises in its coating, based on 100 atom % for the total of the elements silicon, oxygen and carbon within the scope of the aforementioned quantities

in each case as a minimum value: 12, preferably 14, more preferably 18, more preferably 22, more preferably 23 and more preferably 23.9 for silicon and in each case as a maximum value: 30, preferably 28 and more preferably 26.1 atom % Si,
in each case as a minimum value: 16, preferably 19, more preferably 22, more preferably 23, and more preferably 23.9, particularly preferably 25, more preferably 31 and most particularly preferably 34.2 and in each case as a maximum value: 60, preferably 55 and more preferably 50 atom % O and in each case as a minimum value: 10, preferably 15, and more preferably 20, and in each case as a maximum value: 69, preferably 60, more preferably 50, preferably 45 and more preferably 40.4 atom % C, measured using ESCA, preferably on the side remote from the substrate.

It is pointed out that it is particularly preferred in each case that, when in the present context upper and lower limits for specific parameter ranges are stated independently of one another, the first mentioned value in each case of the lower limit is preferably combined with the first mentioned value in each case of the upper limit, this applying analogously to the further mentioned values.

An article according to the invention preferably comprises a plasma polymeric coating which has a gradient.

A person skilled in the art can produce a gradient structure, for example by a temporal variation of the deposition conditions, such as gas composition, coupled in power and total quantity of gas. In this respect, the gradient can relate both to the material composition and to the cross-linking degree or hardness in the layer.

The advantage of a gradient structure is that in this manner, a bonding of the coating to the substrate can be optimized at least to some extent independently of the resulting surface quality of the coating (on the side remote from the substrate).

Furthermore, a person skilled in the art can ensure the desired adhesion between coating and substrate by a suitable pretreatment of the substrate, for example by means of (plasma) purification and activation methods.

Preferred examples of an elastomeric or polymeric substrate are:

NR (natural rubber), CR (chloroprene elastomer), IIR (isobutene-isoprene elastomer), [H]NBR [hydrogenated] (acrylonitrile-butadiene elastomer), AU (polyester urethane), EU (polyether-urethane), EPDM (ethylene-propylene-diene elastomer), MQ (methylene-silicone elastomer), VMQ (vinyl-methyl-silicone elastomer), PMQ (phenyl-methyl-silicone elastomer), FMQ (fluoro-methyl-silicone elastomer), FKM (fluoro-elastomer), FEPM (tetrafluoroethylene-propylene elastomer), FFKM (perfluoro-elastomer), PE (polyethylene), PP (polypropylene), TPU (thermoplastic polyurethane),

Furthermore, an article according to the invention is preferred in which the coating on the side remote from the substrate is additionally provided with an amorphous hydrocarbon coating (a-CH coating).

An a-CH coating is characterized by a content of approximately 20-40% of sp³-hybridization of the carbon. However, practically any ratios between sp³ and sp²-hybrids can be adjusted and thus the hardness can be controlled over wide ranges. If, in such an amorphous, hydrogen-containing layer, the sp³-hybrid content increases and if the hydrogen content simultaneously decreases, then ta-CH coatings are also involved. (See FIG. 29.7 in ISBN 978-3-527-40673-9, Low Temperature Plasmas (Vol. 2); edited by R. Hippler, H. Kersten, M. Schmidt, K. H. Schoenbach). A precise classification of the DLC (Diamond like Carbon) types of layers can be found in the VDI Guideline 2840 or http://www.ist.fraunhofer.de/c-produkte/tab/komplett.html. (t) a-CH layers are special forms of DLC layers.

An a-CH coating can be produced in particular by the use of PECVD processes using hydrocarbon-containing precursors, such as C₂H₂, C₂H₄, C₂H₆. Further information about DLC coatings can be found in the Diamond Films Handbook (2002).

The advantages of an amorphous hydrocarbon coating with its typical hardnesses within a range of from 0.05 to 2000 HV are in particular that the friction coefficient of the surface of the layer can be influenced: such layers are fully covalently bound due to the amorphous structure. Consequently, they have a very low adhesion tendency in contact with metallic contact partners and are advantageous under tribological loads, particularly under mixing and dry friction conditions. For use on elastomers, a-CH coatings in the lower hardness and layer thickness range for these coatings (hardness <1000 HV and layer thickness range up to 1 μm, preferably up to 5 μm) are of particular interest, since both the elastomer and an organosilicon plasma polymeric coating will have significantly lower hardnesses. Modifications of a-CH coatings with Si or Si and O are often also advantageous, as they can reduce the surface energy.

An article of the invention is also further preferred according to the invention in which the plasma polymeric coating is modified with CHₓF_{y}-type groups (y=2 or 3), so that for this special case, the composition of the plasma polymeric coating consists of Si, C, O, F and H (optionally with usual impurities). To produce layers of this type, a person skilled in the art will use partially fluorinated precursors. These partially fluorinated precursors are preferably additionally used, as well as in the last process steps.

An article according to the invention is preferred in which the coating of the substrate (optionally including the a-CH coating) has a thickness of 1 to 10000 nm, preferably 10 to 2000 nm, more preferably 20 to 1000 nm and particularly preferably 50 to 500 nm. Preferred according to the invention is in each case a layer structure as a gradient layer or a multi-layered structure in which the hardness is increased from the substrate to the coating surface (of the side remote from the substrate). It can be preferable in specific applications for supporting layers to also be incorporated in the case of a multi-layered structure.

Supporting layers are layers which ensure a stable mechanical foundation in a layer structure and which support actual, optionally softer functional layers, so that mechanical load can be absorbed and distributed here. They improve the mechanical stability of thin layer systems. Within the organosilicon coatings, a person skilled in the art will increase the content of Si—O and/or Si—CH₂—Si compounds for supporting layers.

The hardness, the degree of cross-linking and the surface energy of the plasma polymeric layers are generally highest for those layers with a high oxygen content. It is the opposite for the flexibility of the layers; this is highest for layers with a low oxygen content.

A person skilled in the art is aware that the flexibility of the sealing material will decrease with an increasing degree of cross-linking of the coating and an increasing coating thickness. This will enable him to influence the tightness.

Furthermore, a person skilled in the art can select the surface energy and hardness of the coating such that a perfect wetting of the surface with the oils or greases to be sealed is provided, so that a good elastohydrodynamic lubrication is ensured.

The article according to the invention is preferably, for example a radial rotary shaft seal, a piston packing, a rod seal or a floating ring seal.

It is preferred according to the invention that the plasma polymeric coating reproduces the surface topography of the elastomeric substrate. This is possible due to the particular characteristics of plasma polymeric layers. In this respect, it is particularly preferred that the surface topography of the elastomeric substrate is configured such that a conveying of lubricant is furthered by a micropump action.

Preferred lubricants are oils, in particular mineral oils, oil mixtures, additivated oils, in particular oils with so-called friction modifiers; lubricating grease.

The micropump action can be created by the coating of already pre-structured sealing surfaces, it being necessary for the coating to replicate the structuring. It is suggested that those structures are used which can be seen using a microscope on an uncoated elastomeric sealing surface just after the run-in phase. However, a clump formation of the coating on the elastomer surface can also further the micropump action.

The articles according to the invention, in particular the preferred embodiments have a surface energy which ensures a surface wetting using typical lubricants, for example chemical oils, as used in automotive engineering. This provides a friction system which is clearly different from a dry solids-solids friction. Furthermore, the articles according to the invention, particularly in preferred embodiments, have a greater hardness than the elastomeric substrate. The thermal conductivity of preferred layers of the invention is within a range of from 0.1 to 0.2 W/m K and thus within the range of many elastomers. However, their thermal resistance can be configured to be significantly higher in the preferred embodiments than that of the elastomers. Due to the three-dimensional cross-linking of plasma polymeric layers, the thermal expansion within the layer is lower than that of elastomers. Furthermore, they have (depending on the embodiment) a high chemical resistance and do not swell up.

Unlike hard substance layers, the plasma polymeric layers in articles according to the invention are able to follow rapid, short-stroke axial movements which the elastomer often has to perform in the sealing region during use. Their hardness is higher than that of the elastomers and therefore their wear behavior, due to the cross-linking typical of plasma polymeric layers, is improved. However, they still have the necessary flexibility.

The low surface energy of the coating means that deposits of degraded oil cannot easily settle in the sealing gap. Furthermore, the plasma polymeric coatings to be used according to the invention cannot harden and become brittle like an elastomer. Bubble formation (blistering) is also reliably avoided.

The plasma-like plasma polymeric coatings described in the prior art (for example in WO 2007/118905) and the previously described plasma-polymeric interlayers (for example DE 134 737 A1) are much poorer than the coatings to be used according to the invention in particular for dynamic applications. The first mentioned layers are too soft and/or have a surface energy which is too low for many of today's standard lubricants. These layers are oloephobic for many mineral oils.

Accordingly, the invention also relates to the use of a plasma polymeric coating, as described in the form of a coating for the articles according to the invention, to improve the dynamic loadability of an elastomeric substrate.

The invention further relates to a process for the production of a sealing article, comprising the steps:
a) preparation of an elastomeric and/or polymeric substrate and
b) deposition of a plasma polymeric layer, as defined above for the articles according to the invention, on at least part of the surface of the substrate.

The process according to the invention preferably also comprises the step:
c) deposition of an amorphous hydrocarbon coating (a-CH coating) on the plasma polymeric coating on the side remote from the substrate or modifying the plasma polymeric coating on the side remote from the substrate, so that it comprises CHₓF_{y} groups where

x=0, 1, 2 or 3 and

y=3−x.

In the following, the invention will be described in more detail using examples; the examples are not to be understood as limiting the invention:

### EXAMPLE 1

For Example 1, the static friction coefficient was determined using conventional experiments from the physics textbook on an inclined plane, whereby a weighed test body (X5CrNi18-9 with a polished surface) was positioned on the rubber plate to be tested and the angle was determined (measured relative to the horizontal) from which the metallic test body was moved by gravity from the rest state to sliding movement.

The sliding friction coefficient was determined by force measurements using tension tests on weighted steel weights (material designation: X5CrNi18-9 with a polished surface) on a planar rubber plate. The force measurement was made in the horizontal parallel to the test plate. In this respect, the static friction was initially overcome and only the force was measured which was necessary to keep the test body moving.

The test material used was an NBR plate with dimensions of 80×200 mm and a Shore A hardness of between 60 and 80 supplied by Benien, the surface of which plate was carefully cleaned using isopropanol. Plasma activation of the substrate was carried out using an H₂/O₂ mixture of 900/200 sccm for 300 sec and 2000 W. All the tests were carried out dry.

Different types of layers, namely two coatings according to the invention and an elastomeric-type plasma polymeric coating (according to WO 2007/118905) were selected as coatings. Further details are provided in Table 1 (layers 1 to 3). All the coatings were smudge-proof on the NBR surface. The coatings were carried out in a 1 m³ plasma installation with laterally attached rod electrodes (for description see ISBN 978-3-86727-548-4 “Aufskalierung plasmapolymerer Beschichtungsverfahren”, pages 21-26 by Dr. Klaus Vissing). The substrates were introduced floating freely in the centre of the chamber.

Layer 3 is characterized by a significantly lower surface energy, compared to layers 1 and 2. For example, layer 3 can no longer be wetted with commercially available engine oil (Megol engine oil HD-C3 SAE 15W-40″, produced by Meguin), the surface is oleophobic. On the other hand, layers 1 and 2 can be wetted.

TABLE 1

| | | | | Layer | | |
|---|---|---|---|---|---|---|
| | | Ratio | Power | thickness | Static friction | Sliding friction |
| Layer | Type of layer | HMDSO/O₂ | [W] | [nm] | coefficient | coefficient |
| Uncoated | | | | | 1.96 | 1.91 |
| 1 | Easy-to-clean | 0.27 | 2500 | 323 | 0.25 | 0.19 |
| 2 | Easy-to-clean | 0.82 | 2200 | 165 | 0.30 | 0.28 |
| 3 | PDMS-type | 3.5 | 700 | 400 | 0.48 | 0.29 |
| | (not acc. to | | | | | |
| | invention) | | | | | |

It is found that each of the plasma polymeric layers used significantly improves the static and sliding friction coefficients.

Layer 2 differs quite substantially from layer 1 in the layer thickness and the higher HMDSO content in the working gas. This results in a considerable increase in the friction coefficient. A minimum layer thickness is obviously necessary in order to effectively and completely cover the elastomer surface.

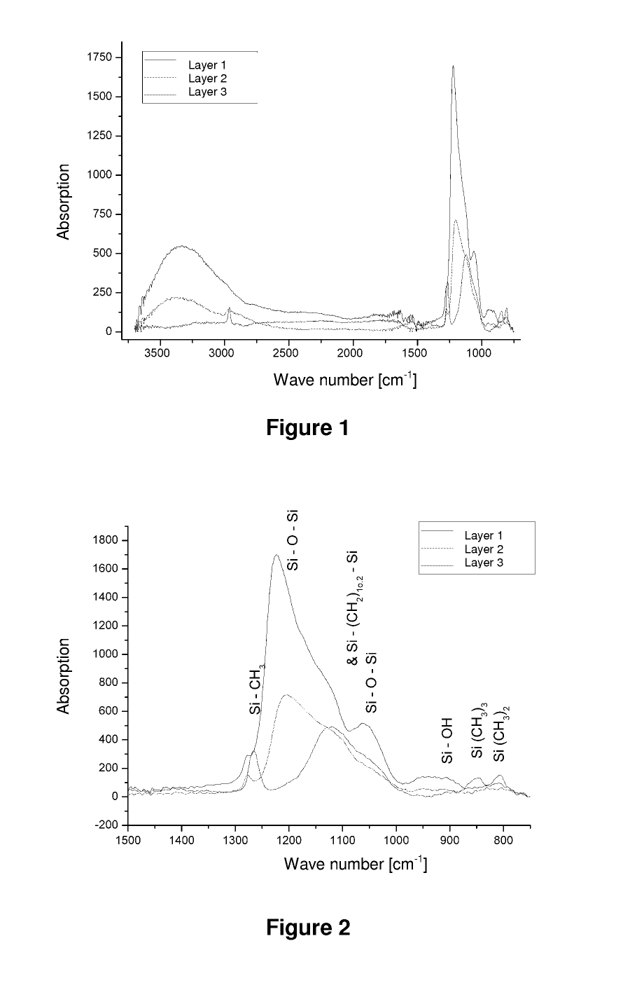

Layer 3 is the most cross-linked and layer 1 is the least cross-linked. This can be seen from ESCA (Table 2) and FTIR measurements (FIGS. 1 and 2).

TABLE 2

| | | O | C | Si |
|---|---|---|---|---|
| | | [at-%] | [at-%] | [at-%] |
| | | O 1s | C 1s | Si 2p |
| Layer | Type of layer | energy max. | energy max. | energy max. |
| 1 | Easy-to-clean | 50.2 | 22.15 | 27.65 |
| | | 532.795 eV | 285.0 eV | 103.76 eV |
| 2 | Easy-to-clean | 40.8 | 33.85 | 25.35 |
| | | 532.663 eV | 285.0 eV | 103.562 eV |
| 3 | PDMS-type (not | 27.5 | 48.0 | 24.5 |
| | acc. to invention) | 532.531 eV | 285.0 eV | 102.836 eV |

FIG. 1 shows an FTIR spectrum of layers 1 to 3,

FIG. 2 shows a detail of an FTIR spectrum of layers 1 to 3.

It can be seen from comparing layers 1 and 3 which differ quite substantially in their hardness, flexibility and degree of cross-linking, that layer 1 produces much better results. The static friction coefficient in particular is significantly improved.

### EXAMPLE 2

An elastomeric viton rotary shaft seal is provided with a plasma polymeric gradient coating approximately 350 nm thick. Deposition takes place according to Table 3 without BIAS support in a 5 m³ installation (for description see ISBN 978-3-86727-548-4 “Aufskalierung plasmapolymerer Beschichtungsverfahren”, pages 21-26 by Dr. Klaus Vissing). As a result, the life of the rotary shaft seal was more than doubled and leakage was reduced.

TABLE 3

| | Partial | Partial | Partial | Partial | Partial |
|---|---|---|---|---|---|
| | step 1 | step 2 | step 3 | step 4 | step 5 |
| Gas flow O₂ | 200 | | | 20 | 100 |
| (cm³/min) | | | | | |
| Gas flow H₂ | 900 | 200 | 200 | 200 | |
| (cm³/min) | | | | | |
| Gas flow | | | 27 | 27 | 27 |
| HMDSO | | | | | |
| (cm³/min) | | | | | |
| Power (W) | 2000 | 1000 | 1000 | 1600 | 2500 |
| Pressure | 0.045 | 0.025 | 0.025 | 0.023 | 0.023 |
| (mbar) | | | | | |
| Time (sec) | 300 | 60 | 60 | 180 | 2400 |

### EXAMPLE 3

In this Example, a thicker coating of approximately 1055 nm is deposited and tested. The coating parameters are shown in Table 4, coating installation as in Example 1

TABLE 4

| | Partial | Partial | Partial | Partial | Partial | Partial |
|---|---|---|---|---|---|---|
| | step 1 | step 2 | step 3 | step 4 | step 5 | step 6 |
| Gas flow O₂ (cm³/min) | 200 | | | 20 | 100 | |
| Gas flow H₂ (cm³/min) | 900 | 200 | 200 | 200 | | 900 |
| Gas flow HMDSO | | | 27 | 27 | 27 | |
| (cm³/min) | | | | | | |
| Power (W) | 2000 | 1000 | 1000 | 1600 | 2500 | 300 |
| Pressure (mbar) | 0.045 | 0.025 | 0.025 | 0.023 | 0.023 | 0.055 |
| Time (sec) | 300 | 60 | 60 | 180 | 8400 | 300 |

### Hardness and Modulus of Elasticity Measurements

The layer hardness and the modulus of elasticity of the layer are measured by nano-indentation. The hardness was 2.74 GPa, the modulus of elasticity was 24.7 GPa. This produces a ratio of hardness to modulus of elasticity of 0.111. (The measurement method is described in Example 2 of WO 2009/056635).

### Surface Energy (Disperse and Polar Proportions)

The surface energy was measured using a dynamic contact angle measurement with a device G2 manufactured by Krüss. For this, six different liquids were selected. Further details concerning the liquids and the contact angles are stated in Table 5. The surface energy is evaluated by Wu's method. The contact angle measurement was made in air at 20° C. The drop volume was up to 6 μl and was added at 11.76 μl/min. An automatic contour analysis was performed on both sides of the drop using a standard drop shape and a linear base line. The device formed the harmonic mean of the contact angle. In the further calculations, only contact angles are considered, bearing in mind an interval width of 68.3% based on the average.

This produces a surface energy of 29.71±0.38 mN/m with a disperse proportion of 23.52±0.21 mN/m and a polar proportion of 6.19±0.16 mN/m.

TABLE 5

| | Surface | Disperse | Polar | | |
|---|---|---|---|---|---|
| | energy of | proportion | proportion | Contact | |
| | liquid | of liquid | of liquid | angle | Error |
| | [mN/m] | [mN/m] | [nN/m] | [°] | [°] |
| Ethylene glycol | 47.7 | 30.9 | 16.8 | 64.3 | 0.24 |
| Diiodine methane | 50.8 | 50.8 | 0.0 | 73.4 | 0.76 |
| Water | 72.8 | 21.8 | 51.0 | 95.0 | 0.51 |
| Glycol | 63.4 | 37.0 | 26.4 | 80.3 | 0.72 |
| n-Decane | 23.9 | 23.9 | 0.0 | 79.7 | 1.47 |
| Benzyl alcohol | 38.9 | 29.0 | 9.9 | 42.2 | 0.13 |

### ESCA—Analysis

The ESCA analysis of this coating shows the following element composition:

| | |
|---|---|
| Si | 28.1 at % |
| C | 22.4 at % |
| O | 49.5 at % |

This produces the following substance amount ratios:

n(O):n(Si)=1.76

n(C):N(Si)=0.80

The maximum energy position of the silicon peak, after correction, is at 285 eV, for the carbon peak at 103.5 eV, for the oxygen peak at 533.0 eV. Compared to a trimethylsiloxy-terminated polydimethylsiloxane (PDMS) with a kinematic viscosity of 350 mm²/s at 25° C. and a density of 0.97 g/mL at 25° C., this results in a displacement of 0.81 eV to higher energies for the silicon peak and of 0.54 eV to higher energies for the oxygen peak.

### EXAMPLE 4

To check the coating success, rotary shaft seals of a different construction and optionally with a different pretreatment were coated and subsequently the coating success was checked by ESCA measurements (double measurement in two positions). Rotary shaft seal 4a consists of NBR (nitrile butyl rubber). The (“thin”) rotary shaft ring consists of FKM (fluorinated rubber).

The coating was performed using parameters from Example 3. The oil AK 100 000 produced by Wacker Chemie was used as reference values.

The results are shown in Tables 6a and 6b.

TABLE 6a

| Substrate | Pos. | 0 1s | C 1s | Si 2p | C/Si | O/Si | Total |
|---|---|---|---|---|---|---|---|
| Shaft seal 4a, | 2 | 34.88 | 48.51 | 16.00 | 3.03 | 2.18 | 99.86 |
| rinsed with IPA | | | | | | | |
| Shaft seal 4a, | 1 | 32.49 | 52.16 | 14.47 | 3.60 | 2.25 | 99.80 |
| rinsed with IPA | | | | | | | |
| Shaft seal 4a, | Average | 33.69 | 50.34 | 15.24 | 3.30 | 2.21 | 99.83 |
| rinsed with IPA | | | | | | | |
| Shaft seal 4a, | 1 | 33.41 | 49.76 | 15.85 | 3.14 | 2.11 | 99.90 |
| rinsed with | | | | | | | |
| n-hexane | | | | | | | |
| Shaft seal 4a, | 2 | 34.32 | 47.73 | 17.07 | 2.80 | 2.01 | 99.88 |
| rinsed with | | | | | | | |
| n-hexane | | | | | | | |
| Shaft seal 4a, | Average | 33.87 | 48.75 | 16.46 | 2.96 | 2.06 | 99.89 |
| rinsed with | | | | | | | |
| n-hexane | | | | | | | |
| Shaft seal 4a | 2 | 32.24 | 47.52 | 19.13 | 2.48 | 1.69 | 99.37 |
| Shaft seal 4a | 1 | 34.47 | 44.02 | 20.05 | 2.20 | 1.72 | 99.19 |
| Shaft seal 4a | Average | 33.36 | 45.77 | 19.59 | 2.34 | 1.70 | 99.28 |
| Shaft seal (thin) | 1 | 34.05 | 45.64 | 19.48 | 2.34 | 1.75 | 100.00 |
| Shaft seal (thin) | 2 | 34.23 | 45.49 | 19.68 | 2.31 | 1.74 | 100.00 |
| Shaft seal (thin) | Average | 34.14 | 45.57 | 19.58 | 2.33 | 1.74 | 100.00 |
| AK100 000 | 1 | 23.93 | 52.63 | 23.44 | 2.25 | 1.02 | 100.00 |
| AK100 000 | 2 | 24.04 | 52.55 | 23.41 | 2.24 | 1.03 | 100.00 |
| AK100 000 | Average | 23.99 | 52.59 | 23.43 | 2.25 | 1.02 | 100.00 |
| Shaft seal 4a, | 2 | 16.16 | 80.99 | 2.33 | 34.76 | 6.94 | 99.75 |
| cleaned | | | | | | | |
| Shaft seal 4a, | 1 | 17.48 | 79.98 | 2.05 | 39.01 | 8.53 | 99.67 |
| cleaned | | | | | | | |
| Shaft seal 4a, | Average | 16.82 | 80.49 | 2.19 | 36.75 | 7.68 | 99.71 |
| cleaned | | | | | | | |

TABLE 6b

| | | | | | | | Average of differences of | |
|---|---|---|---|---|---|---|---|---|
| | | | | Peak position,corrected to | | | Si 2p peak | |
| | Peak position,measured (eV) | | | C1s = 285 eV | | | compared to AK 100 000 | |
| Substrate | C 1s | 0 1s | Si 2p | C 1s | Substrate | C 1s | 0 1s | Si 2p |
| Shaft seal 4a, | 281.87 | 529.52 | 100.17 | 285 | Shaft seal 4a, | 281.87 | 529.52 | 100.17 |
| rinsed with IPA | | | | | rinsed with IPA | | | |
| Shaft seal 4a, | 282.13 | 529.71 | 100.23 | 285 | Shaft seal 4a, | 282.13 | 529.71 | 100.23 |
| rinsed with IPA | | | | | rinsed with IPA | | | |
| Shaft seal 4a, | 282.00 | 529.62 | 100.20 | 285 | Shaft seal 4a, | 282.00 | 529.62 | 100.20 |
| rinsed with IPA | | | | | rinsed with IPA | | | |
| Shaft seal 4a, | 281.93 | 529.71 | 100.1 | 285 | Shaft seal 4a, | 281.93 | 529.71 | 100.1 |
| rinsed with | | | | | rinsed with | | | |
| n-hexane | | | | | n-hexane | | | |
| Shaft seal 4a, | 281.83 | 529.38 | 100.03 | 285 | Shaft seal 4a, | 281.83 | 529.38 | 100.03 |
| rinsed with | | | | | rinsed with | | | |
| n-hexane | | | | | n-hexane | | | |
| Shaft seal 4a, | 281.88 | 529.55 | 100.07 | 285 | Shaft seal 4a, | 281.88 | 529.55 | 100.07 |
| rinsed with | | | | | rinsed with | | | |
| n-hexane | | | | | n-hexane | | | |
| Shaft seal 4a | 282.032 | 529.65 | 100.5 | 285 | Shaft seal 4a | 282.032 | 529.65 | 100.5 |
| Shaft seal 4a | 281.9 | 529.71 | 100.5 | 285 | Shaft seal 4a | 281.9 | 529.71 | 100.5 |
| Shaft seal 4a | 281.97 | 529.68 | 100.50 | 285 | Shaft seal 4a | 281.97 | 529.68 | 100.50 |
| Shaft seal (thin) | 281.83 | 529.38 | 100.03 | 285 | Shaft seal (thin) | 281.83 | 529.38 | 100.03 |
| Shaft seal (thin) | 281.83 | 529.52 | 99.97 | 285 | Shaft seal (thin) | 281.83 | 529.52 | 99.97 |
| Shaft seal (thin) | 281.83 | 529.45 | 100.00 | 285 | Shaft seal (thin) | 281.83 | 529.45 | 100.00 |
| AK100 000 | 281.67 | 529.25 | 99.37 | 285 | AK100 000 | 281.67 | 529.25 | 99.37 |
| AK100 000 | 281.9 | 529.58 | 99.7 | 285 | AK100 000 | 281.9 | 529.58 | 99.7 |
| AK100 000 | 281.79 | 529.42 | 99.54 | 285 | AK100 000 | 281.79 | 529.42 | 99.54 |

In use, the coated rotary shaft seals had a substantially longer service life. Noticeable is the relatively high carbon content in the coatings, which can be attributed to the fact that (in addition to other elements) carbon was also incorporated in the coating from the substrate.

1. Sealing article, comprising an elastomeric and/or polymeric substrate and a plasma polymeric coating arranged thereon and consisting of carbon, silicon, oxygen, hydrogen and (i) fluorine or (ii) no fluorine and optionally usual impurities, the following relationships applying to the substance amount ratios in the plasma polymeric coating:
1.3:1≦n(O):n(Si)≦3.0:1, and
0.3:1≦n(C):n(Si)≦5.0:1.

2. Sealing article according to claim 1, wherein the sealing article is suitable for dynamic loads.

3. Sealing article according to claim 1, wherein in the ESCA spectrum of the plasma polymeric layer, with calibration on the aliphatic proportion of the C 1s peak at 285.00 eV, compared to a trimethylsiloxy-terminated polydimethylsiloxane (PDMS) with a kinematic viscosity of 350 mm²/s at 25° C. and a density of 0.97 g/·mL at 25° C.,
the Si 2p peak has a bonding energy value which is displaced by more than 0.4 eV to higher bonding energies or
the O 1s peak has a bonding energy value which is displaced by more than 0.50 eV to higher bonding energies.

4. Article according to claim 1, wherein the sealing article has on the side of the plasma polymeric coating remote from the substrate a sliding friction coefficient of ≦0.25.

5. Article according to claim 1, wherein the plasma polymeric layer has a hardness of from 1.5 to 5 GPa or a modulus of elasticity of from 10 to 50 GPa, measured by means of nanoindentation.

6. Article according to claim 1, wherein the plasma polymeric coating has on the side remote from the substrate a water contact angle of from 70° to 100° or a wear coefficient of ≦3*10⁻³ mm³/N km.

7. Article according to claim 1, wherein the plasma polymeric coating contains, based on 100 atom % for the total of the elements silicon, oxygen and carbon:

| | |
|---|---|
| silicon | 12 to 30 atom % |
| oxygen | 16 to 60 atom %, and |
| carbon | 10 to 69 atom %. |

8. Article according to claim 1, wherein the ratio of hardness to modulus of elasticity is ≧0.1 for the plasma polymeric coating.

9. Article according to claim 1, wherein the surface energy of the plasma polymeric coating on the side remote from the substrate is from 25 to 40 mN/m.

10. Article according to claim 1, wherein the plasma polymeric coating has a gradient structure.

11. Article according to claim 1, wherein the plasma polymeric coating is provided with an additional amorphous hydrocarbon coating (a-CH coating) on the side remote from the substrate.

12. Article according to claim 1, wherein the plasma polymeric coating comprises on the side remote from the substrate CHₓF_{y} groups where
x=0, 1, 2 or 3, and
y=3−x.

13. Article according to claim 1, wherein the plasma polymeric coating has a thickness of from 1 to 10000 nm.

14. Article according to claim 1, wherein the article is a rotary shaft seal, a radial rotary shaft seal, a piston packing, a rod seal or a floating ring seal.

15. Article according to claim 1, wherein the plasma polymeric coating reproduces the surface topography of the elastomeric and/or polymeric substrate.

16. Article according to claim 15, wherein the surface topography is configured such that a lubricant conveyance is furthered by a micropump action.

17. Method of improving the dynamic loadability of an elastomeric and/or polymeric substrate, using a plasma polymeric coating as defined in claim 1.

18. Process for the production of a sealing article, comprising the steps of:
a) preparation of an elastomeric and/or polymeric substrate and
b) deposition of a plasma polymeric layer as defined in claim 1, on at least part of the surface of the substrate.

19. Process according to claim 18, also comprising the step of:
c) deposition of an amorphous hydrocarbon coating (a-CH coating) on the plasma polymeric coating on the side remote from the substrate or modifying the plasma polymeric coating on the side remote from the substrate, so that it comprises CHₓF_{y} groups, where
x=0, 1, 2 or 3, and
y=3−x.

20. Sealing article according to claim 2, wherein:
in the ESCA spectrum of the plasma polymeric layer, with calibration on the aliphatic proportion of the C 1s peak at 285.00 eV, compared to a trimethylsiloxy-terminated polydimethylsiloxane (PDMS) with a kinematic viscosity of 350 mm²/s at 25° C. and a density of 0.97 g/·mL at 25° C.,
the Si 2p peak has a bonding energy value which is displaced by more than 0.4 eV to higher bonding energies and/or
the O 1s peak has a bonding energy value which is displaced by more than 0.50 eV to higher bonding energies;
the sealing article has on the side of the plasma polymeric coating remote from the substrate a sliding friction coefficient of ≦0.25;
the plasma polymeric layer has a hardness of from 1.5 to 5 GPa and/or a modulus of elasticity of from 10 to 50 GPa, measured by means of nanoindentation;
the plasma polymeric coating has on the side remote from the substrate a water contact angle of from 70° to 100° and/or a wear coefficient of ≦3*10⁻³ mm³/N km;
the plasma polymeric coating contains, based on 100 atom % for the total of the elements silicon, oxygen and carbon:

| | |
|---|---|
| silicon | 12 to 30 atom % |
| oxygen | 16 to 60 atom %, and |
| carbon | 10 to 69 atom %; |

the ratio of hardness to modulus of elasticity is ≧0.1 for the plasma polymeric coating;
the surface energy of the plasma polymeric coating on the side remote from the substrate is from 25 to 40 mN/m; and
the plasma polymeric coating has a gradient structure.

21. Article according to claim 20, wherein:
the plasma polymeric coating has a thickness of from 1 to 10000 nm;
the article is a rotary shaft seal, a radial rotary shaft seal, a piston packing, a rod seal or a floating ring seal;
the plasma polymeric coating reproduces the surface topography of the elastomeric and/or polymeric substrate; and
the surface topography is configured such that a lubricant conveyance is furthered by a micropump action.

22. Method of improving the dynamic loadability of an elastomeric and/or polymeric substrate, using a plasma polymeric coating as defined in claim 20.

23. Method of improving the dynamic loadability of an elastomeric and/or polymeric substrate, using a plasma polymeric coating as defined in claim 21.

24. Process for the production of a sealing article, comprising the steps of:
a) preparation of an elastomeric and/or polymeric substrate and
b) deposition of a plasma polymeric layer as defined in claim 20, on at least part of the surface of the substrate.

25. Process according to claim 24, also comprising the step of:
c) deposition of an amorphous hydrocarbon coating (a-CH coating) on the plasma polymeric coating on the side remote from the substrate or modifying the plasma polymeric coating on the side remote from the substrate, so that it comprises CHₓF_{y} groups where
x=0, 1, 2 or 3, and
y=3−x.

26. Sealing article according to claim 1, wherein the substance amount ratio in the plasma polymeric coating is:
0.5:1≦(n(H)+n(F)):n(C)≦3.0:1.

27. Article according to claim 8, wherein the ratio of hardness to modulus of elasticity is ≧0.11 for the plasma polymeric coating.
